(19) United States
(12) Patent Application Publication
(10) Pub. No.: US 2005/0220990 A1
(43) Pub. Date: Oct. 6, 2005

(54) Magnetic film forming method, magnetic pattern forming method and magnetic recording medium manufacturing method

(75) Inventors: Tsutomu Aoyama, Tokyo (JP); Shunji Ishio, Tokyo (JP); Hirotaka Ito, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: TDK Corporation, Tokyo (JP)

(21) Appl. No.: 11/049,724

(22) Filed: Feb. 4, 2005

(30) Foreign Application Priority Data
Feb. 6, 2004 (JP) P.2004-030310

(51) Int. Cl. C23C 14/00; B05D 5/12

(52) U.S. Cl. 427/127

(57) ABSTRACT

An Ag ion 6 is locally implanted into a thin film 4 containing, as main components, at least one of Fe and Co and at least one of Pd and Pt and a heat treatment is then carried out, and a portion 7 into which the Ag ion 6 is implanted becomes a portion 9 having a large coercive force and a portion 8 into which the Ag ion 6 is not locally implanted becomes a portion 10 having a small coercive force.

### BACKGROUND OF THE INVENTION

The present invention relates to a method of forming a magnetic film, a method of forming a magnetic pattern and a method of manufacturing a magnetic recording medium, and more particularly to a method of forming a magnetic film which can process a magnetic film including a recording portion and a non-recording portion in accordance with a recording pattern.

The performance of a hard disk drive (HDD) has remarkably been enhanced continuously with the development of a computer as a mass storage device capable of carrying out the high-speed access and transfer of data. In particular, an areal density has been enhanced at an annualized rate of 60% to 100% for these 10 years and a further enhancement in the recording density has been required.

In order to enhance the recording density of the hard disk drive (HDD), it is necessary to reduce a track width or a recording bit length. However, there is a problem in that adjacent tracks are apt to interfere with each other if the track width is reduced. More specifically, the reduction in the track width causes a problem in that magnetic recording information is easily overwritten over the adjacent track in recording and a problem in that a cross talk is apt to be generated by a leaking magnetic field from the adjacent track in reproduction. Both of these problems cause a reduction in the S/N ratio of a reproducing signal and a deterioration in an error rate.

For these problems, a magnetic recording medium of a discrete track type (hereinafter referred to as a discrete track medium) has been proposed as a method of reducing an interference between the adjacent tracks and implementing a high track density. The discrete track medium proposed currently is obtained by providing a trench between the tracks of a magnetic film to be a recording portion (a guard band) to magnetically separate each track from the adjacent track. In this method, however, it is hard to implement the stable flying of a magnetic head over the magnetic recording medium because a physical trench is present between the tracks.

On the other hand, although it is possible to stabilize the flying characteristics of the magnetic head over the magnetic recording medium by carrying out a flattening processing after filling the trench between the tracks with a non-magnetic substance, there is a problem in that a manufacturing process is complicated and a manufacturing cost is thus increased.

As a method of avoiding these problems, there has been investigated a processing method of irradiating ion on a magnetic film to locally modify a magnetic characteristic (for example, see Japanese Publication JP-T-2002-501300 and JP-A-2003-22525). In a method described in JP-T-2002-501300, a light ion is irradiated on a laminated film and the atom of an interface between the laminated films is subjected to mixing by the shock, thereby modifying the magnetic characteristic of an irradiating portion. In a method described in JP-A-2003-22525, moreover, local heat generation caused by the irradiation of ion beam is utilized to modify the magnetic characteristic of the irradiating portion.

### SUMMARY OF THE INVENTION

The invention provides new technique for avoiding the conventional problems described above, and it is a first object of the invention to provide a method of forming a magnetic film which can form a magnetic film including portions having different coercive forces. Moreover, it is a second object of the invention to provide a method of forming a magnetic pattern which utilizes the method and it is a third object of the invention to provide a method of manufacturing a magnetic recording medium which utilizes the method.

A method of forming a magnetic film according to the invention which attains the first object is characterized in that Ag ion is locally implanted into a thin film containing, as main components, at least one of Fe and Co and at least one of Pd and Pt and a heat treatment is then carried out.

According to the invention, in the portion of the film containing, as main components, at least one of Fe and Co and at least one of Pd and Pt into which the Ag ion is not implanted, a lower coercive force is obtained without a sufficient change to a CuAuI type ordered structure having a high magnetic anisotropy even if the heat treatment is carried out. On the other hand, in the portion into which the Ag ion is locally implanted, a magnetic film having the CuAuI type ordered structure is obtained by the heat treatment so that a very high magnetic anisotropy is acquired. More specifically, Ag acts to promote the change to the CuAuI type ordered structure in the heat treatment. Therefore, the portion having the Ag ion implanted therein is sufficiently changed to have the CuAuI type ordered structure by a subsequent heat treatment.

As a result, there is formed a magnetic film in which the portion having the Ag ion implanted locally therein is sufficiently changed to have the CuAuI type ordered structure, and therefore, has a large coercive force and the portion into which the Ag ion is not implanted is not sufficiently changed to have the CuAuI type ordered structure and has a small coercive force.

According to the method of forming a magnetic film in accordance with the invention, therefore, it is possible to form a magnetic film having different coercive forces between the portion into which the Ag ion is implanted and the portion into which the Ag ion is not implanted. For this reason, it is possible to form a discrete track medium without providing a conventional trench. Consequently, it is possible to form a magnetic pattern substantially having no surface concavo-convex portion.

The method of forming a magnetic film according to the invention is characterized in that a portion having the Ag ion implanted therein which is obtained after the heat treatment has a CuAuI type ordered structure. According to the invention, since the portion having the Ag implanted therein which is obtained after the heat treatment has the CuAuI type ordered structure, it exhibits a very high magnetic anisotropy. As a result, the magnetic film having the high magnetic anisotropy produces an advantage that the thermal stability of a recording magnetization can be enhanced.

In the method of forming a magnetic film in accordance with the invention, it is preferable that the thin film should be obtained by laminating a film containing at least one of Fe and Co as the main component and a film containing at least one of Pd and Pt as the main component.

In the method of forming a magnetic film in accordance with the invention, it is preferable that the thin film should be a compositionally modulated film obtained by modulating compositions of at least one of Fe and Co and at least one of Pd and Pt in a direction of a thickness of the film. According to the invention, it is supposed that an interface diffusion is caused during the heat treatment so that the activation energy of the diffusion is reduced if the thin film is the compositionally modulated film. Consequently, only the portion having the Ag ion implanted therein can be changed to have the CuAuI type ordered structure at a low heat treatment temperature.

A method of forming a magnetic pattern according to the invention which attains the second object is characterized in that an Ag ion is implanted, by using a mask, into a predetermined portion of a thin film containing, as main components, at least one of Fe and Co and at least one of Pd and Pt and a heat treatment is then carried out.

According to the invention, in the same manner as in the case of the method of forming a magnetic film, there is formed a magnetic pattern in which the portion having the Ag ion implanted locally therein is sufficiently changed to have the CuAuI type ordered structure and thus has a large coercive force, and the portion having no Ag ion implanted therein is not sufficiently changed to have the CuAuI type ordered structure but has a small coercive force. According to the method of forming a magnetic pattern in accordance with the invention, therefore, it is possible to form a discrete track medium having a magnetic pattern without providing a conventional trench. Consequently, it is possible to form a magnetic pattern substantially having no surface concavo-convex portion.

In a method of manufacturing a magnetic recording medium according to the invention which attains the third object, a method of manufacturing a magnetic recording medium having at least a non-magnetic substrate and a magnetic film provided on the non-magnetic substrate is characterized in that the magnetic film is obtained by locally implanting an Ag ion into a thin film containing, as main components, at least one of Fe and Co and at least one of Pd and Pt and then carrying out a heat treatment.

According to the invention, it is possible to manufacture the magnetic recording medium such as a discrete track medium including a predetermined magnetic pattern without forming a conventional trench. Therefore, it is possible to manufacture a magnetic recording medium substantially having no surface concavo-convex portion.

A method of manufacturing a magnetic recording medium according to the invention is characterized in that the local implantation of the Ag ion is carried out by using a mask.

As described above, according to the method of forming a magnetic film, the method of forming a magnetic pattern and the method of manufacturing a magnetic recording medium in accordance with the invention, it is possible to increase the coercive force of the portion into which the Ag ion is implanted. As a result, it is possible to form the magnetic film having different coercive forces between the portion into which the Ag ion is implanted and the portion into which the Ag ion is not implanted. Therefore, it is possible to form a desirable magnetic pattern substantially having no surface concavo-convex portion by implanting the Ag ion into a predetermined portion using a mask, for example.

By forming, as a track pattern taking the shape of a concentric circle, the portion into which the Ag ion is implanted on a disk-shaped non-magnetic substrate, particularly, it is possible to manufacture a magnetic recording medium such as a discrete track medium having a predetermined magnetic pattern to be the portion into which the Ag ion is implanted without forming a conventional trench. The magnetic recording medium thus manufactured substantially has no surface concavo-convex portion and a manufacturing cost can also be reduced.

### BRIEF DESCRIPTION OF THE DRAWINGS

FIGS. 1(a) to 1(c) are views showing a process according to an example of the method of forming a magnetic film in accordance with the invention; FIG. 1(a) shows the sectional configuration of a thin laminated film, FIG. 1 (b) shows the sectional configuration of a step of implanting an Ag ion into the thin film, and FIG. 1(c) shows the sectional configuration of a magnetic film according to the invention which is formed by the execution of a heat treatment;

FIG. 2 is a sectional view in the direction of lamination according to an example of a manner in which an underlayer film and an intermediate film are provided between a substrate and the magnetic film in the magnetic film illustrated in FIG. 1(c); and

FIG. 3 is a view showing a process according to an example of a method of forming a compositionally modulated film according to the invention.

### DETAILED DESCRIPTION OF THE PREFERRED EMBODIMENTS

A method of forming a magnetic film, a method of forming a magnetic pattern and a method of manufacturing a magnetic recording medium according to the invention will be sequentially described below with reference to the drawings. The scope of the invention is not restricted by an embodiment which will be described below.

(Magnetic Film Forming Method)

The method of forming a magnetic film according to the invention is characterized in that an Ag ion 6 is locally implanted into a thin film 4 containing, as main components, at least one of Fe and Co and at least one of Pd and Pt which are formed on a substrate 1 and a heat treatment is then carried out as shown in FIG. 1.

A non-magnetic substrate is used for the substrate 1, and an aluminum alloy substrate, a glass substrate and a silicon substrate which are generally used as the substrate of a magnetic film are taken as an example.

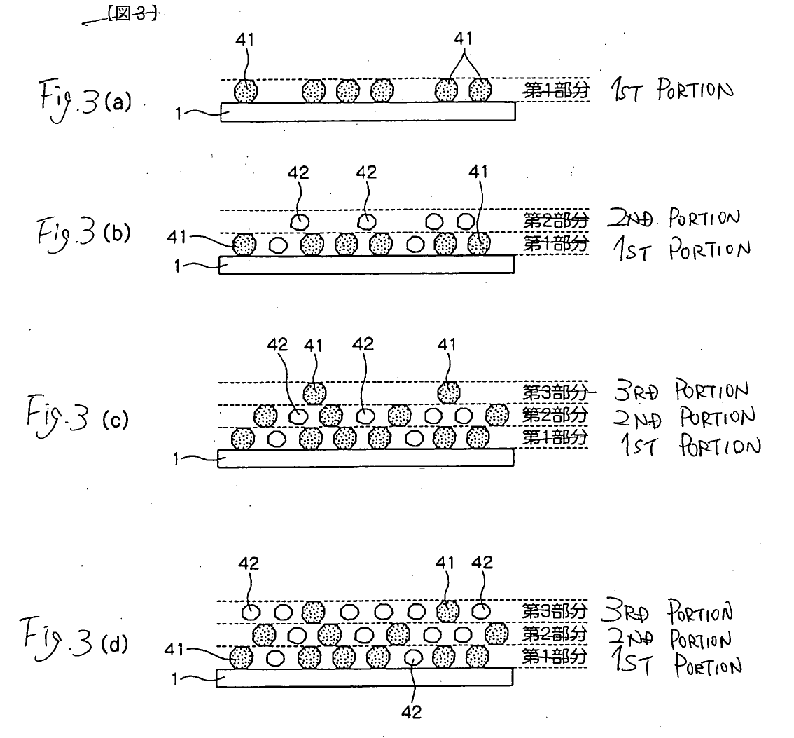

The thin film 4 formed on the substrate 1 may be a thin laminated film obtained by alternately providing a first film 2 containing at least one of Pd and Pt as a main component and a second film 3 containing at least one of Fe and Co as the main component or may be a compositionally modulated film formed by alternately deposing at least one of Pd and Pt (a Pt atom 41 in FIG. 3) and at least one of Fe and Co (an Fe atom 42 in FIG. 3).

In the case in which the thin film 4 is a thin laminated film, the first film 2 is not particularly restricted if the film contains at least one of Pd and Pt as a main component. For example, Pd, Pt and Pd—Pt can be preferably taken as at least one of Pd and Pt, and Pt is particularly preferable. Moreover, the second film 3 is not particularly restricted if the film contains at least one of Fe and Co as the main component. For example, Fe, Co and Fe—Co can be preferably taken as at least one of Fe and Co, and Fe is particularly preferable.

For the thin laminated film, it is desirable that the first film 2 and the second film 3 should be constituted by an element of Pt—Fe, Pt—Co or Pt—Co—Fe which is provided on the substrate 1 and is then heat treated, and can be a magnetic film having a high magnetic anisotropy. In particular, it is desirable that the thin laminated film should be obtained by providing a Pt film to be the first film 2 and an Fe film to be the second film 3.

The thin laminated film can be formed by various film forming means such as sputtering. For the lamination of the first film 2 and the second film 3, it is possible to carry out sputtering over each target having respective film forming elements at a predetermined power for a predetermined time by using the same target, thereby forming the first film 2 and the second film 3 constituted by a desirable composition.

In the case in which the thin film 4 is a compositionally modulated film, a compositionally modulated film having the composition of at least one of Fe and Co and at least one of Pd and Pt modulated is not particularly restricted. For example, there is desired a compositionally modulated film having the composition of at least one of Fe and Co and at least one of Pd and Pt modulated in the direction of the thickness of the film as shown in FIG. 3. The compositionally modulated film is formed as a result of a deposition with the regulation of a film forming rate in such a manner that the thicknesses of the atoms of at least one of Fe and Co and at least one of Pd and Pt are equal to or smaller than the thickness of a monoatomic layer thereof The “modulation” represents a state in which the composition of each layer in the direction of the thickness of a film is not obtained by only a single atom as in a conventional laminated film in which monoatomic layers are alternately provided but at least one of Fe and Co and at least one of Pd and Pt are continuously changed with different compositions from each other in the direction of the thickness of the film.

For the compositionally modulated film, it is possible to illustrate a compositionally modulated film in which Pt and Fe are alternately deposited and a portion having a higher rate of Pt and a portion having a higher rate of Fe are provided periodically.

In the compositionally modulated film thus illustrated, a rate of Pt to the total of Pt and Fe is preferably higher than 50 atomic % and equal to or lower than 90 atomic % and is more preferably equal to or higher than 60 atomic % and equal to or lower than 90 atomic % in the portion having a higher rate of Pt. By depositing the portion having a higher rate of Pt within the range of the rate described above, it is possible to form a magnetic film with a CuAuI type ordered structure having a high magnetic anisotropy by a subsequent heat treatment. In some cases in which the rate of Pt is higher than 90 atomic %, it is impossible to form the magnetic film with the CuAuI type ordered structure having the high magnetic anisotropy even if the heat treatment is carried out.

For such a compositionally modulated film, more specifically, a compositionally modulated film including three portions having ratios of a Pt atom to an Fe atom of 3:1, 1:1 and 1:3 as one cycle is taken as an example.

The method of forming a compositionally modulated film is not particularly restricted but the following methods using the Pt atom and the Fe atom are taken as an example as shown in FIG. 3.

(1) The Pt atom 41 corresponding to 75% of a necessary amount for forming a Pt monoatomic atom is deposited on the non-magnetic substrate 1 by sputtering. The Pt atom 41 has an amount of 75% at which a perfect monoatomic layer cannot be formed. Therefore, a first portion thus formed has 25% of defects as shown in FIG. 3(a).

(2) Next, the Fe atom 42 corresponding to 75% of a necessary amount for forming an Fe monoatomic layer is deposited on the first portion by the sputtering. 25% of the Fe atom 42 fills in the defect of the first portion by a surface diffusing effect, and at the same time, 50% of the residue of the Fe atom 42 forms a second portion. As a result, the first portion is set to have a ratio of Pt to Fe of 3:1 as shown in FIG. 3(b) and the second portion has 50% of defects.

(3) Then, the Pt atom 41 corresponding to 75% of a necessary amount for forming a Pt monoatomic layer is deposited on the second portion by the sputtering. 50% of the Pt atom 41 fills in the defect of the second portion by the surface diffusing effect, and at the same time, 25% of the residue of the Pt atom 41 forms a third portion. As a result, the second portion is set to have a ratio of Pt to Fe of 1:1 as shown in FIG. 3(c) and the third portion has 75% of defects.

(4) Thereafter, the Fe atom 42 corresponding to 75% of a necessary amount for forming the Fe monoatomic layer is deposited on the third portion by the sputtering. The Fe atom 42 is deposited to fill in all of the defects of the third portion by the surface diffusing effect, and the third portion is set to have a ratio of Pt to Fe of 1:3 as shown in FIG. 3(d).

The film formed at the steps of (1) to (4) has the three portions (the first portion, the second portion and the third portion) set to be one cycle, and has a composition modulating structure in which the portions have different ratios of the Pt atom to the Fe atom of 3:1, 1:1 and 1:3 respectively. Such a compositionally modulated film has a distortion generated by the periodic shift of a composition ratio as compared with a laminated film in which monoatomic layers are provided alternately. For this reason, it is supposed that the mutual diffusion of the Pt atom 41 and the Fe atom 42 is easily caused and the CuAuI type ordered structure can be thus obtained at a lower energy.

The thin film 4 is formed until a thickness (which implies a total thickness) is 3 nm to 30 nm, for example. In some cases in which the thickness of the thin film 4 is smaller than 3 nm, it is impossible to form a magnetic film with the CuAuI type ordered structure having a high magnetic anisotropy by a subsequent heat treatment. If the thickness of the thin film 4 is greater than 30 nm, a granular growth becomes remarkable in the subsequent heat treatment. As a result, in some cases in which a magnetic film which is obtained is applied to a magnetic recording medium, for example, a bad influence is caused, that is, a medium noise is increased. In the case in which the thin film 4 is a thin laminated film, the thickness of the first film 2 and that of the second film 3 may be equal to or different from each other or the thickness of each of the first films 2 and that of each of the second films 3 may be equal to or different from each other. If the thickness of the thin film 4 is 3 nm to 30 nm, moreover, the number of laminated layers is not particularly restricted.

The thin film 4 has a disordered phase with a face centered cubic structure (fcc) and has a low magnetic anisotropy and coercive force before the heat treatment, and is formed by regulating the composition of the film in such a manner that it becomes a magnetic film with the CuAuI type ordered structure having a high magnetic anisotropy after the heat treatment. The disordered phase of the face centered cubic structure (fcc) has a random array of the Fe atom and the Pt atom, for example, and has a low magnetic anisotropy and coercive force. Moreover, the CuAuI type ordered structure implies a face centered tetragonal structure (fct) and has an atomic arrangement in which the Fe atom and the Pt atom are laminated alternately in a c-axis direction, for example.

For the composition of the thin film to be the magnetic film with the CuAuI type ordered structure having a high magnetic anisotropy after the heat treatment, a composition of F₁₋ₓMₓ (F represents at least one of Fe and Co, M represents at least one of Pd and Pt, and x represents an atomic ratio of 0.3 to 0.65) is desirable. The composition of the thin film 4 is regulated to have such a composition. In the invention, the magnetic film obtained after the heat treatment has the CuAuI type ordered structure with the composition of F₁₋ₓMₓ (F represents at least one of Fe and Co, M represents at least one of Pd and Pt, and x represents an atomic ratio of 0.3 to 0.65). Therefore, the magnetic film obtained after the heat treatment has a very high magnetic anisotropy. When the crystal structure of the thin film is changed from the disordered phase with the face centered cubic structure (fcc) to an ordered phase with the face centered tetragonal structure (fct) in which a lattice constant is increased in an a-axis direction and is reduced in the c-axis direction by the heat treatment, a super lattice is formed on a so-called atomic level in which the Fe atom and the Pt atom are alternately provided for each atomic layer in the c-axis direction for the reduction, for example. Therefore, the anisotropy of the atomic arrangement produces a uniaxial magnetic anisotropy which is very high in the c-axis direction. As a result, the magnetic film having a high magnetic anisotropy produces an advantage that the thermal stability of a recording magnetization can be enhanced. The change from the disordered phase to the ordered phase described above is generally referred to as an order-disorder transformation.

The thin film 4 contains, as main components, at least one of Fe and Co and at least one of Pd and Pt, and usually includes other components to be a magnetic recording medium of an isolated particle system. For the other components, oxide and fluorocarbon are taken as an example.

Ag is implanted, by ion implantation, into the thin film 4 which has not been heat treated. Ag has an effect of promoting a change to the CuAuI type ordered structure. The change to the CuAuI type ordered structure of the thin film 4 having the Ag ion 6 implanted therein is promoted in a subsequent heat treatment. More specifically, there is an effect of easily carrying out the change to the CuAuI type ordered structure. In the invention, the Ag ion 6 is locally implanted into the predetermined portion of the thin film 4 and the heat treatment is then carried out so that only a portion 7 having the Ag ion 6 implanted therein can easily be changed to have the CuAuI type ordered structure and a change to a magnetic film 11 having a large coercive force can be performed. As a result, the portion 7 into which the Ag ion 6 is implanted becomes a portion 9 having a large coercive force, and a portion 8 into which the Ag ion 6 is not implanted becomes a portion 10 having a small coercive force.

It is preferable that the amount of implantation of the Ag ion 6 should be 1 to 3 atomic % with the composition of the portion 7 into which the Ag ion 6 is implanted. When the Ag ion 6 within this range is implanted, the portion 7 into which the Ag ion 6 is implanted is heat treated to become the portion 9 having a large coercive force and the portion 8 into which the Ag ion 6 is not implanted is heat treated to become the portion 10 having a small coercive force. In some cases in which the amount of implantation of the Ag ion 6 is smaller than 1 atomic %, the portion 7 subjected to the implantation cannot be sufficiently changed to have the CuAuI type ordered structure so that the magnetic film 11 having a high magnetic anisotropy and a large coercive force cannot be obtained. On the other hand, in some cases in which the amount of implantation of the Ag ion 6 is larger than 3 atomic %, the magnetic film 11 having a large coercive force and a small surface roughness cannot be obtained.

The implantation of the Ag ion 6 is carried out by the ion implantation. The ion implantation uses an ion implanting equipment. In the case in which the Ag ion 6 is to be implanted, it is desirable that an implanting voltage should be set within a range of 20 keV to 60 keV when the thickness of the thin film 4 is 3 nm to 30 nm. By implanting the Ag ion 6 at the implanting voltage within this range, it is possible to implant the Ag ion 6 into each portion in the direction of the thickness of the thin film 4, for example. In the case in which the thickness of the thin film 4 is small, it is desirable that the implanting voltage should be set to have a smaller value within the range. In the case in which the thickness of the thin film 4 is great, it is desirable that the implanting voltage should be set to have a greater value within the range. In some cases in which the ion implanting voltage is lower than 20 keV, the change to the CuAuI type ordered structure cannot be sufficiently carried out so that the magnetic film 11 having a high magnetic anisotropy and a large coercive force cannot be obtained when the thickness of the thin film 4 is 3 nm to 30 nm. On the other hand, in some cases in which the ion implanting voltage is higher than 60 keV, Ag in the surface layer portion of the thin film is decreased and the change to the CuAuI type ordered structure cannot be sufficiently carried out so that the magnetic film 11 having a high magnetic anisotropy and a large coercive force cannot be obtained when the thickness of the thin film 4 is 3 nm to 30 nm.

The heat treatment in the invention serves to sufficiently change only the portion 7 into which the Ag ion 6 is implanted to have the CuAuI type ordered structure, thereby obtaining the magnetic film 11 including the portion 9 having a large coercive force. More specifically, the local implantation of the Ag ion 6 can promote the change to the CuAuI type ordered structure in only the portion 7 into which the Ag ion 6 is implanted by a subsequent heat treatment. Consequently, the portion 7 into which the Ag ion 6 is implanted can be changed to have the CuAuI type ordered structure with a large coercive force by the heat treatment, and the portion 8 into which the Ag ion 6 is not implanted can be brought into the state of the portion 10 having a small coercive force.

For example, in a patterned magnetic recording medium such as a magnetic recording medium of a discrete track type or a magnetic recording medium of a discrete bit type, it is desirable that the portion 9 having a large coercive force and the portion 10 having a small coercive force should have a difference in the coercive force of 2000 Oe or more. The patterned magnetic recording medium having the difference in the coercive force can decrease the width of a track or a recording bit length without causing a reduction in an S/N ratio and a deterioration in an error rate.

The conditions of the heat treatment are set in such a manner that only the portion 7 into which the Ag ion 6 is implanted can be sufficiently changed to have the CuAuI type ordered structure. The conditions of the heat treatment are not absolutely determined depending on the amount of implantation of the Ag ion 6, and the pressure of a heat treatment atmosphere is preferably equal to or lower than 5×10⁻⁶ Torr, for example. In some cases in which the pressure of the heat treatment atmosphere is higher than 5×10⁻⁶ Torr, a deterioration is caused by the oxidation of the magnetic film 11. Moreover, the heat treatment temperature is preferably set within a range of 300° C. to 750° C. In some cases in which the heat treatment temperature is lower than 300° C., the change to the CuAuI type ordered structure in the portion 7 having the Ag ion 6 implanted therein is not sufficiently carried out. In some cases in which the heat treatment temperature is higher than 750° C., the shape of the surface of the magnetic film 11 is changed. Furthermore, the heat treatment time is preferably 5 to 10000 seconds. In some cases in which the heat treatment time is shorter than 5 seconds, the change to the CuAuI type ordered structure in the portion 7 having the Ag ion 6 implanted therein is not sufficiently carried out. In some cases in which the heat treatment time is longer than 10000 seconds, the substrate 1 is deformed depending on the material of the substrate 1 which is used.

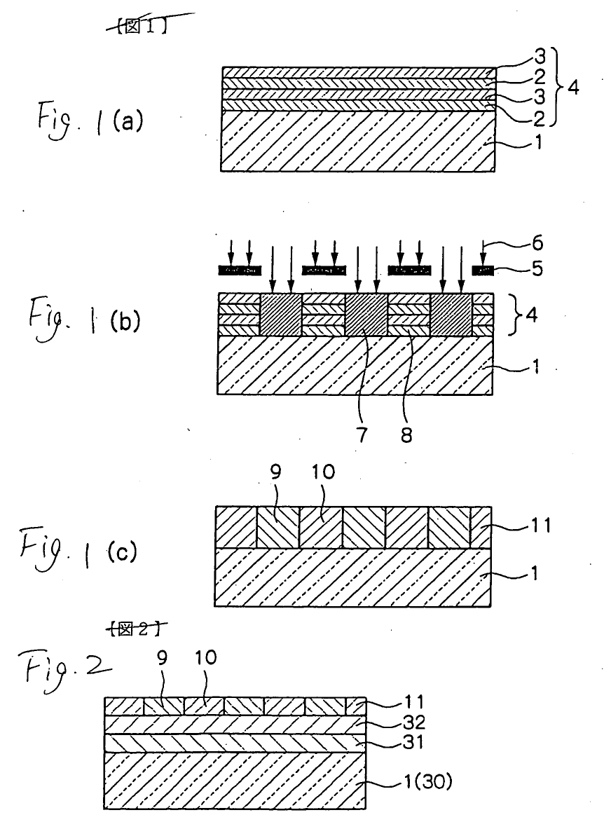

In the method of forming a magnetic film according to the invention described above, an underlayer film 31 and an intermediate film 32 can be provided as a ground between the substrate 1 and the magnetic film 11 as shown in FIG. 2. The magnetic film 11 including the underlayer film 31 and the intermediate film 32 has an advantage that it is more excellent in a crystal orientation and a recording characteristic as compared with a magnetic film which does not include them.

The underlayer film 31 is provided to be a soft magnetic underlayer on the substrate 1 formed by a non-magnetic material, and is formed by a material of NiFe, NiFeNb or FeCo in a thickness of 5 nm to 200 nm, for example. The underlayer film 31 can be formed by sputtering, for example.

The intermediate film 32 is provided on the underlayer film 31 in order to control the crystal orientation of the magnetic film, and is formed by a material such as MgO in a thickness of 0.5 nm to 5 nm, for example. The intermediate film 32 can also be formed by the sputtering, for example.

(Magnetic Pattern Forming Method)

Next, description will be given to the method of forming a magnetic pattern according to the invention.

The method of forming a magnetic pattern according to the invention is characterized in that the local implantation of the Ag ion is carried out by using a mask in the method of forming a magnetic film described above. More specifically, the same method is characterized in that the Ag ion is implanted by using the mask into the predetermined portion of a thin film containing, as main components, at least one of Fe and Co and at least one of Pd and Pt and a heat treatment is then carried out. In this case, the thin film may be the thin film 4 in which the first film 2 containing at least one of Pd and Pt as a main component and the second film 3 containing at least one of Fe and Co as a main component are laminated as shown in FIG. 1, for example, or may be a compositionally modulated film in which at least one of Pd and Pt and at least one of Fe and Co are laminated alternately as shown in FIG. 3, for example.

The material of a mask 5 is not particularly restricted but it is possible to optionally use various materials represented by a resist and a silicon stencil which are formed by photolithography. In the invention, particularly, the opening portion of the mask 5 is set to have a track pattern taking the shape of a concentric circle for forming a discrete track medium, for example. Consequently, the Ag ion can be mixed into the thin film in the same pattern as the track pattern. By setting the opening portion of the mask 5 to have a dot-like pattern for forming a discrete bit medium, for example, it is possible to mix the Ag ion into the thin film in the same pattern as the dot pattern.

By implanting the Ag ion into the film which has not been heat treated by such a method, the portion having the Ag ion implanted therein can be set to have the track pattern taking the shape of a concentric circle having a large coercive force, and the portion having no Ag ion implanted therein can be set to have a pattern having a small coercive force.

According to the method of forming a magnetic pattern in accordance with the invention, therefore, it is possible to form a portion having a large coercive force to take the shape of a pattern, thereby forming a magnetic pattern substantially having no surface concavo-convex portion in a very simple process.

As a mask for forming a track pattern taking the shape of a concentric circle to be provided in a discrete track medium, for example, it is possible to use a mask having a mask pattern in which the opening width of the mask is approximately 30 nm to 250 nm and the track pitch of the mask is approximately 50 nm to 300 nm. As a mask for forming a dot-like bit pattern to be provided on a discrete bit medium, moreover, it is possible to use a mask having a mask pattern in which the opening diameter of the mask is approximately 10 nm to 100 nm and the dot pitch of the mask is approximately 20 nm to 200 nm, for example.

(Magnetic Recording Medium Manufacturing Method)

Next, description will be given to the method of manufacturing a magnetic recording medium according to the invention.

The method of manufacturing a magnetic recording medium according to the invention utilizes the method of forming a magnetic pattern described above, and the method of manufacturing a magnetic recording medium having at least a non-magnetic substrate and a magnetic film provided on the non-magnetic substrate is characterized in that an Ag ion is locally implanted into a thin film containing, as main components, at least one of Fe and Co and at least one of Pd and Pt, and a heat treatment is then carried out. Since the magnetic recording medium to be manufactured is formed in the same configuration as the configuration shown in FIG. 2, each film will be described below by using designations utilized in FIG. 1 or 2.

In the magnetic recording medium to be manufactured, the underlayer film 31 and the intermediate film 32 shown in FIG. 2 are provided as the ground between a non-magnetic substrate 30 (corresponding to the reference numeral 1 in FIG. 1) and the magnetic film 11. The magnetic recording medium with such a structure has an effect of concentrating a recording magnetic field in a perpendicular recording system on the recording portion of a magnetic film well (obtaining an excellent recording efficiency).

According to the method of manufacturing a magnetic recording medium in accordance with the invention, it is possible to manufacture a magnetic recording medium such as a discrete track medium or a discrete bit medium to be a patterned medium including a predetermined magnetic pattern without forming a conventional trench. Consequently, it is possible to manufacture a magnetic recording medium substantially having no surface concavo-convex portion.

### EXAMPLE

The invention will be described below in more detail with reference to examples of the method of manufacturing a magnetic recording medium.

### Example 1

By using a glass substrate having a thickness of 0.635 mm as the non-magnetic substrate 30, NiFeNb was formed thereon by sputtering so as to be the underlayer film 31 in a thickness of 150 nm, and furthermore, MgO was formed thereon by the sputtering so as to be the intermediate film 32 in a thickness of 3 nm. A Pt atom 41 corresponding to 75% of a necessary amount for forming a Pt single atomic layer was deposited, by the sputtering, on the intermediate film 32 thus formed, and subsequently, an Fe atom 42 corresponding to 75% of a necessary amount for forming an Fe single atomic layer was deposited by the sputtering. Then, the deposition of the Pt atom 41 and that of the Fe atom 42 were alternately repeated, and the depositions were alternately carried out until the number of repetitions is 63. Thus, a thin film was formed. The thin film thus obtained was a compositionally modulated film having a ratio of the Pt atom 41 to the Fe atom 42 of 3:1, 1:1 and 1:3 as one cycle respectively, and the atomic composition ratio of the compositionally modulated film was Pt₄₅Fe₅₅ as a result of a composition analysis to be carried out by an energy dispersive spectrometer (EDS) and the thin film had a total thickness of 20 nm. The thin film was formed by providing a Pt target and an Fe target on a rotatable target plate, rotating the target plate and stopping the target plate in a predetermined position, and carrying out sputtering over the respective targets.

Next, an Ag ion was implanted into the thin film thus obtained so that seven types of films (samples 2 to 8) were fabricated. The Ag ion was implanted by using an ion implanting equipment (manufactured by Nisshin Denki Co., Ltd.; Model No. NH20SR). The amount of implantation of the Ag ion in the thin film was expressed in a value obtained by measuring each of the thin films subjected to the implantation by means of the Rutherford backscattering spectroscopy (RBS). In the samples 2 to 8, the Ag ion was implanted into the thin film in the amount of implantation of 1 to 20 atomic % at an implanting voltage of 40 keV as shown in Table 1.

The seven types of films (the samples 2 to 8) thus obtained and the film (the sample 1) into which the Ag ion is not implanted were heat treated respectively so that a magnetic film was fabricated. The heat treatment was carried out on a condition of 600° C. and 3600 seconds in a vacuum atmosphere of 5×10⁻⁷ Torr or less. The magnetic characteristic of the magnetic film obtained after the heat treatment was examined and a result is shown in Table 1. The crystal structure of the magnetic film was determined by an X-ray diffraction. Referring to the magnetic characteristic, a coercive force Hc in an in-plane direction and a saturation magnetization Ms were measured by means of a vibrating sample magnetometer (VSM), respectively.

TABLE 1

| | Amount of | | | |
|---|---|---|---|---|
| | implantation of | | Saturation | |
| | Ag | Coercive force | magnetization | |
| | (atomic %) | (Oe) | (G) | Evaluation |
| Sample 1 | 0 | 6200 | 1050 | ▴ |
| Sample 2 | 1 | 10760 | 1020 | ∘ |
| Sample 3 | 2 | 10360 | 890 | ∘ |
| Sample 4 | 2.5 | 11890 | 750 | ∘ |
| Sample 5 | 3 | 11130 | 710 | ∘ |
| Sample 6 | 5 | 6597 | 440 | ▴ |
| Sample 7 | 10 | 2176 | 350 | ▴ |
| Sample 8 | 20 | 1307 | 210 | ▴ |

As is apparent from the result of the Table 1, in case of the samples 2 to 5 according to the invention, all of them had large coercive forces and a difference from the coercive force of the sample 1 including no Ag was equal to or larger than 2000 Oe, and a high saturation magnetization could be obtained. For the preferable range of the recording portion of a magnetic recording medium, a coercive force was equal to or larger than 8000 Oe and a saturation magnetization was equal to or larger than 700 G All of the samples 2 to 5 according to the invention were within the preferable range. On the other hand, in case of the samples 6 to 8 having the amounts of implantation of the Ag ion of 5 atomic %, 10 atomic % and 20 atomic %, all of them had small coercive forces and had low saturation magnetizations departing from the preferable range for the recording portion of the magnetic recording medium.

### Example 2

Four types of films (samples 9 to 12) were fabricated in the same manner as in the example 1 except that an implanting voltage was set to be 20 keV to carry out implantation. In the samples 9 to 12, as shown in Table 2, the Ag ion was implanted into the thin film in the amounts of implantation of 1 to 3 atomic % at an implanting voltage of 20 keV Referring to the magnetic characteristic of the film thus fabricated, a coercive force Hc in an in-plane direction and a saturation magnetization Ms were measured by means of a vibration sample type magnetometer (VSM) respectively in the same manner as in the example 1. A result is shown in Table 2.

TABLE 2

| | Amount of | | Saturation |
|---|---|---|---|
| | implantation of Ag | Coercive force | magnetization |
| | (atomic %) | (Oe) | (G) |
| Sample 1 | 0 | 6200 | 1050 |
| Sample 9 | 1 | 9013 | 1030 |
| Sample 10 | 2 | 11880 | 880 |
| Sample 11 | 2.5 | 10810 | 820 |
| Sample 12 | 3 | 10320 | 800 |

As is apparent from the result of the Table 2, in case of the samples 9 to 12 according to the invention, all of them had large coercive forces and a difference from the coercive force of the sample 1 including no Ag was equal to or larger than 2000 Oe, and a high saturation magnetization could be obtained.

### Example 3

Three types of films (samples 13 to 15) were fabricated in the same manner as in the example 1 except that an implanting voltage was set to be 60 keV to carry out implantation. In the samples 13 to 15, as shown in Table 3, the Ag ion was implanted into the thin film in the amounts of implantation of 1 to 2.5 atomic % at an implanting voltage of 60 keV Referring to the magnetic characteristic of the film thus fabricated, a coercive force Hc in an in-plane direction and a saturation magnetization Ms were measured by means of a vibration sample type magnetometer (VSM) respectively in the same manner as in the example 1. A result is shown in Table 3.

TABLE 3

| | Amount of | | Saturation |
|---|---|---|---|
| | implantation of Ag | Coercive force | magnetization |
| | (atomic %) | (Oe) | (G) |
| Sample 1 | 0 | 6200 | 1050 |
| Sample 13 | 1 | 9753 | 990 |
| Sample 14 | 2 | 11150 | 820 |
| Sample 15 | 2.5 | 12850 | 760 |

As is apparent from the result of the Table 3, in case of the samples 13 to 15 according to the invention, all of them had large coercive forces and a difference from the coercive force of the sample 1 including no Ag was equal to or larger than 2000 Oe, and a high saturation magnetization could be obtained.

Accordingly, the Ag ion having the effect of promoting the change to the CuAuI type ordered structure is locally implanted in a predetermined amount into the thin film, and the heat treatment is then carried out to promote the change to the CuAuI type ordered structure of the portion into which the Ag ion is implanted. Consequently, it is possible to obtain a magnetic film in which a portion into which the Ag ion is implanted has a large coercive force and a portion into which the Ag ion is not implanted has a small coercive force.

1. A method of forming a magnetic film comprising:
providing a thin film containing, as main components, at least one of Fe and Co and at least one of Pd and Pt;
locally implanting Ag ion into the thin film; and
subjecting a heat treatment.

2. The method of forming a magnetic film according to claim 1, wherein a portion having the Ag ion implanted therein which is obtained after the heat treatment has a CuAuI type ordered structure.

3. The method of forming a magnetic film according to claim 1, wherein the thin film is obtained by laminating a film containing the at least one of Fe and Co as the main component and a film containing the at least one of Pd and Pt as the main component.

4. The method of forming a magnetic film according to claim 1, wherein the thin film is a compositionally modulated film obtained by modulating compositions of the at least one of Fe and Co and the at least one of Pd and Pt in a direction of a thickness of the film.

5. A method of forming a magnetic pattern comprising the steps of:
implanting Ag ion by using a mask into a predetermined portion of a thin film containing, as main components, at least one of Fe and Co and at least one of Pd and Pt; and
subjecting a heat treatment.

6. A method of manufacturing a magnetic recording medium having at least a non-magnetic substrate and a magnetic film provided on the non-magnetic substrate, comprising:
providing a thin film containing, as main components, at least one of Fe and Co and at least one of Pd and Pt;
locally implanting Ag ion into; and
subjecting a heat treatment.

7. The method of manufacturing a magnetic recording medium according to claim 6, wherein the local implantation of the Ag ion is carried out by using a mask.
